(19) United States
(12) Patent Application Publication
(10) Pub. No.: US 2024/0208858 A1
(43) Pub. Date: Jun. 27, 2024

(54) Smooth Surface Diamond Composite Films

(71) Applicant: AKHAN Semiconductor, Inc,, Gurnee, IL (US)

(72) Inventors: Ernest Schirmann, Lake Zurich, IL (US); Kiran Kumar Kovi, Lisle, IL (US)

(21) Appl. No.: 18/545,288

(22) Filed: Dec. 19, 2023

Related U.S. Application Data
(60) Provisional application No. 63/434,286, filed on Dec. 21, 2022.

(51) Int. Cl. C03C 17/22; C23C 16/27; C23C 16/46

(52) U.S. Cl. CPC C03C 17/22; C23C 16/271; C23C 16/463; C03C 2217/28; C03C 2217/78; C03C 2218/152

(57) ABSTRACT

A diamond coated glass structure can include a glass substrate with a deposited nanocrystalline diamond coated on the glass substrate. An ultrananocrystalline diamond layer can be deposited on the deposited nanocrystalline diamond. The combination of deposited nanocrystalline diamond and ultrananocrystalline diamond can have less than 9 nanometer RMS surface roughness.

### RELATED APPLICATION

This application claims the priority benefit of U.S. Provisional Patent Application No. 63/434,286, filed on Dec. 21, 2022, which is hereby incorporated by reference in its entirety.

### FIELD OF THE INVENTION

This invention is generally related to systems and methods for diamond coating of substrates or parts using chemical vapor deposition (CVD). Equipment and methods selected to realize high quality composite diamond films with low surface roughness suitable for covers, displays, or optical equipment are disclosed.

### BACKGROUND

Diamond films or coatings can be used for protecting optical systems, coatings for consumer applications such smartphone or watch displays, coatings for tooling or mechanical parts, coatings for chemical protection, or in electrical or semiconductor applications. Advantageously, diamond films provide increased hardness, scratch resistance, water resistance, and various unique electrical properties. However, commercially practical diamond films or coatings remain limited due to cost and time required for depositing usefully thick diamond coatings on glass substrates.

What is needed are glass/diamond structures and processing techniques that provide or allow for optically clear, smooth, and scratch resistant diamond coatings.

### SUMMARY

Disclosed herein is a new and improved system and method for a diamond coating using CVD systems. A diamond coated glass structure can include a glass or other suitable transparent substrate with a CVD deposited nanocrystalline diamond coated on the substrate. An ultrananocrystalline diamond layer can be deposited on the CVD deposited nanocrystalline diamond. The combination of CVD deposited nanocrystalline diamond and ultrananocrystalline diamond can have less than 9 nanometer RMS surface roughness.

In some embodiments the CVD deposited diamond layer comprises a diamond layer having thickness between 20 and 500 nanometers.

In some embodiments the CVD deposited diamond layer comprises a 70-500 nanometers thick diamond film having at least 50% of diamond grains sized between 3 nanometers and 150 nanometers.

In some embodiments the ultrananocrystalline diamond layer comprises a diamond layer having thickness up to 500 nanometers.

In some embodiments the ultrananocrystalline diamond layer comprises a less than 50 nanometers thick diamond film having at least 50% of diamond grains sized between 2 nanometers and 10 nanometers.

In some embodiments the combination of the CVD deposited diamond layer, an ultrananocrystalline diamond layer deposited on the CVD deposited diamond layer, and the glass substrate provides transmission of light with a transmissivity in excess of at least one of 0.80 and 0.90 at wavelengths ranging between 500 and 600 nanometers.

In some embodiments the combination of the CVD deposited diamond layer, an ultrananocrystalline diamond layer deposited on the CVD deposited diamond layer, and the glass substrate provides haze of less 5%

In some embodiments the substrate has a dimension of at least one centimeter and can be sized to be at least one square centimeter.

In some embodiments the glass substrate comprises at least one of a soda, aluminosilicate, and borosilicate glass.

In some embodiments the glass substrate is chemically modified by replacement of at least some sodium ions with potassium ions.

In some embodiments the CVD deposited diamond layer is deposited on the glass substrate at a temperature below 600 degrees Celsius.

In some embodiments an oleophobic or other additional coating can be deposited on the ultrananocrystalline diamond layer.

In some embodiments the ultrananocrystalline diamond layer and the nanocrystalline diamond layer cover a top surface and at least one of a side surface of the glass substrate.

In some embodiments the ultrananocrystalline diamond layer is one of less than thickness of the nanocrystalline diamond layer.

In some embodiments the ultrananocrystalline diamond layer comprises a less than 50 nanometers thick diamond film having at least 50% of diamond grains sized between 2 nanometers and 10 nanometers.

Other systems, methods, aspects, features, embodiments and advantages of the system and method disclosed herein will be, or will become, apparent to one having ordinary skill in the art upon examination of the following drawings and detailed description. It is intended all such additional systems, methods, aspects, features, embodiments and advantages be included within this description, and be within the scope of the accompanying claims.

### BRIEF DESCRIPTION OF THE DRAWINGS

It is to be understood that the drawings are solely for purpose of illustration. Furthermore, the components in the figures are not necessarily to scale, emphasis instead being placed upon illustrating the principles of the system disclosed herein. In the figures, like reference numerals designate corresponding parts throughout the different views.

FIG. 1A is an exemplary schematic diagram of a glass substrate having one side being diamond coated with nanocrystalline (NCD) and ultrananocrystalline (UNCD) diamond layers;

FIG. 1B is an exemplary schematic diagram of a glass substrate diamond coated with nanocrystalline (NCD) and ultrananocrystalline (UNCD) diamond layers;

FIG. 2A is an exemplary block diagram of an embodiment of a method for fabricating a glass substrate with nanocrystalline (NCD) and ultrananocrystalline (UNCD) diamond layers; and

FIG. 2B is an exemplary block diagram of an embodiment of a method for fabricating a chemically modified glass substrate with nanocrystalline (NCD) and ultrananocrystalline (UNCD) diamond layers.

### DETAILED DESCRIPTION

The following detailed description, which references to and incorporates the drawings, describes and illustrates one or more specific embodiments. These embodiments, offered not to limit, but only to exemplify and teach, are shown and described in sufficient detail to enable those skilled in the art to practice what is claimed. Thus, for the sake of brevity, the description may omit certain information known to those of skill in the art.

As used in this disclosure, the terms “layer”, “film”, and “coated” can be interchangeably used, and refer to thin deposited, chemically formed, grown materials, or otherwise situated materials on a substrate that can itself be a layer, film or coating. Diamond layers or films can include intrinsic diamond, diamond-like material, or diamond with small amounts of graphite or other materials. Diamond lattice structure can be selectively modified and can include provision of varying sp2/sp3 carbon materials positioned through selective seeding or etch, nucleation or growth process parameters including gas composition, pressure, and temperature among other parameters, selective laser annealing, particle bombardment or doping, or use of laser pulse to grow diamond. Modification of diamond layers or films by oxygen termination, hydrogen termination, chlorine or fluorine functionalization are additional embodiments.

The diamond structure and manufacturing method described herein can incorporate systems and methods previously disclosed and described in U.S. Patent Publication No. 2013/0026492, by Adam Khan, published on Jan. 31, 2013; U.S. Pat. No. 8,354,290, issued to Anirudha Sumant, et al, on Jan. 15, 2013; U.S. Pat. No. 8,933,462, issued to Adam Khan on Jan. 13, 2015; U.S. Patent Publication No. 2015/0206749, by Adam Khan, published on Jul. 23, 2015; and U.S. Patent Publication No. 2015/0295134, by Adam Khan, et al, published on Oct. 15, 2015, all of which are fully incorporated herein by reference.

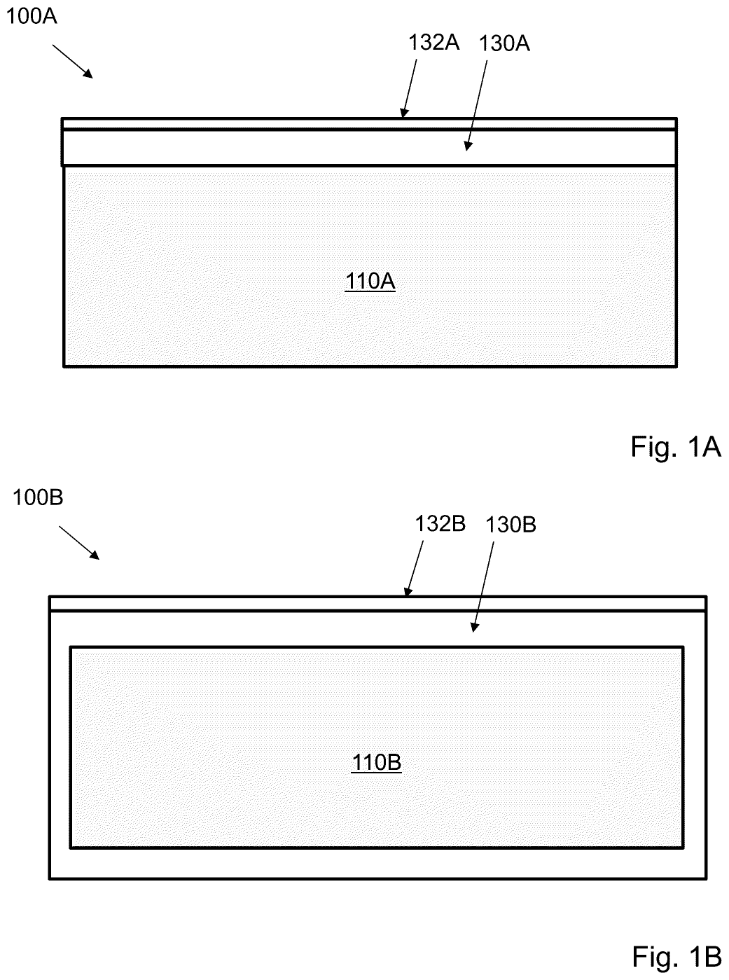

FIG. 1A is an exemplary schematic diagram of a glass substrate having one side being diamond coated with nanocrystalline (NCD) and ultrananocrystalline (UNCD) diamond layers. As illustrated with respect to FIG. 1A, a system and method provided herein allow manufacture of a partially diamond coated glass structure 100A. The glass structure 100A includes a glass substrate 110A having a first side, a second side, and an edge. As will be later discussed, in some embodiments the glass structure can be chemically modified using ion substitution techniques. In one embodiment, a nanocrystalline diamond layer 130A is CVD deposited on one side (e.g. top side) of the glass substrate 110A. In some embodiments, the nanocrystalline layer 130A can have a thickness of between 20 and 500 nanometers with grain sizes between 10 and 200 nanometers. In one embodiment, the CVD deposited diamond layer comprises a 70-500 nanometers (or alternatively, 70-300 nm) thick diamond film having at least 50% of diamond grains sized between 10 nanometers and 500 nanometers. Additionally, using CVD or other suitable deposition techniques, an ultrananocrystalline diamond layer 132A can be deposited on the nanocrystalline diamond layer 130A. In some embodiments, ultrananocrystalline layer 132A can have a thickness of between 20 and 500 nanometers with grain sizes between 2 and 10 nanometers. In some embodiments the ultrananocrystalline diamond layer is less than thickness of the nanocrystalline diamond layer. In some embodiments the ultrananocrystalline diamond layer comprises a less than 500, 300, 200, or less nanometers thick diamond film having at least 50% of diamond grains sized between 2 nanometers and 10 nanometers.

FIG. 1B is an exemplary schematic diagram of a glass substrate coated with nanocrystalline (NCD) and ultrananocrystalline (UNCD) diamond layers. diagram of a glass substrate having one side being diamond coated with nanocrystalline (NCD) and ultrananocrystalline (UNCD) diamond layers. As illustrated with respect to FIG. 1B, a system and method provided herein allow manufacture of a fully diamond coated glass structure 100B. The glass structure 100B includes a glass substrate 110B having a first side, a second side, and an edge. As will be later discussed, in some embodiments the glass structure can be chemically modified using ion substitution techniques. In one embodiment, a nanocrystalline diamond layer 130B is CVD deposited on all sides, edges, and corners of the glass substrate 110B. In some embodiments, the nanocrystalline layer 130B can have a thickness of between 20 and 500 nanometers with grain sizes less than diamond film thickness and generally selected to be between 10 and 200 nanometers. Thickness can be uniform on all surfaces, or alternatively, can vary depending on diamond coats on the top, bottom, or edges. In one embodiment, the CVD deposited diamond layer comprises a diamond film having at least 50% of diamond grains sized between 10 nanometers and 500 nanometers, with grain sizes selected to be less than diamond film thickness. In some embodiments, diamond film thickness can be less than 500 nm, less than 300 nm, less than 200 nm, or less than 150 nm. In some embodiments, diamond film thickness is greater than 70 nm. Additionally, using CVD or other suitable deposition techniques, an ultrananocrystalline diamond layer 132B can be deposited on the nanocrystalline diamond layer 130B. In some embodiments, ultrananocrystalline layer 132B can have a thickness of between 20 and 500 nanometers with grain sizes between 2 and 10 nanometers. In some embodiments, ultrananocrystalline layer 132B can have a thickness of less than 50 nanometers.

As will be understood, various types of glass substrates can be used in structures such as described with respect to FIGS. 1A and B. For example, the glass can be a silicate glass, such as an alkali silicate glass, soda lime glass, an alkali aluminosilicate glass, an aluminosilicate glass, a borosilicate glass, an alkali aluminogermanate glass, an alkali germanate glass, an alkali gallogermanate glass, and combinations thereof. Structures can also be fabricated on infrared (IR) substrate materials including but not limited to Silicon (Si), Zinc Sulfide (ZnS), Zinc Selenide (ZnSe), Germanium (Ge), Magnesium Fluoride (MGF2), Sapphire (Al2O3), Aluminum Oxynitride (AlxOyNz), Spinel (MgAl2O4), Calcium Fluoride (CaF2), Sodium Chloride (NaCl). In some embodiments, multiple types of glass or IR materials can be fused or layered together to provide a substrate. Other examples of glass types and compositions suitable for use are described more fully in U.S. Pat. No. 8,232,218, assigned to Corning, Inc. As described in this disclosure, the glass substrate can be ion exchangeable. In one embodiment, chemical modification can include subjecting diamond coated glass to an ion exchange process. As used herein, the term “ion exchange” or “ion substitution” is understood to mean that the glass is capable of being chemically modified by ion exchange processes that are known to those skilled in the art. Such ion exchange processes include, but are not limited to, treating the glass with a solution containing ions having a larger ionic radius than that of the ions that are present in the glass surface, replacing the smaller ions with the larger ions. In one embodiment of this process, at least some ions of a first element in a surface region in the glass article are exchanged with ions of a second element, wherein each of the ions of the second element has an ionic radius that is greater than that of the ion of the first element that is being replaced. In one embodiment, the first and second elements are alkali metals. The replacement of sodium (Na+ ions) with potassium (K+ ions) is a non-limiting example of such an ion exchange. Alternatively, other alkali metal ions having larger atomic radii, such as rubidium or cesium, could replace smaller alkali metal ions in the glass. In another embodiment, the smaller alkali metal ions could be replaced by silver (Ag+) ions. In some embodiments, additional elements such as Li+, Rb+, Cs+, Cd2+, Zn2+ or Cu+/Cu2+ can be used. As will be understood, ion exchange can be done before or after diamond coating, and multiple ion exchange events can occur during glass processing.

Ion exchange may be carried out using those methods known in the art and described herein. Depending on ion penetrance depth and other characteristics, chemical modification by ion exchange of a glass substrate can result in glass strengthening, hardening, or both. In one embodiment, the glass is immersed in a molten salt bath comprising an alkali metal salt such as, for example, potassium nitrate (KNO3), for a predetermined time period to achieve ion exchange. In some embodiments, the glass substrate can be chemically modified in a single ion exchange step. In some embodiments, the glass substrate is immersed in a molten salt bath containing a salt of the larger alkali metal cation. In some embodiments, the molten salt bath contains or consists essentially of salts of the larger alkali metal cation. In some embodiments single ion exchange process may take place at a temperature below 600° C., while in other embodiments the temperature can be between 275° C. and 550° C. for a time sufficient to achieve the desired ion depth penetrance (which in some embodiments can be increased as thickness of glass increases, and in some embodiments can be between 5 and 300 microns).

In another embodiment, a glass substrate can be chemically modified in a two-step or dual ion exchange method. In the first step of this process embodiment, the glass substrate is ion exchanged in the first molten salt bath. After completion of the first ion exchange, the glass can be optionally diamond coated, and then immersed in additional ion exchange baths (e.g., a second ion exchange bath). Additional or second ion exchange baths can have the same composition as the first ion exchange bath. Alternatively, additional or second ion exchange baths can have different compositions and/or operated at differing immersion time lengths and temperatures than the first ion exchange bath.

In some embodiments, the ion exchange treated glass substrate with a nanocrystalline and ultrananocrystalline composite diamond coatings can be used as a cover glass for housing a consumer electronic display. For example, either untreated or ion exchange treated glass substrates with diamond coatings are especially suitable for glass covers, or displays (e.g., LCD displays), assembled in small form factor electronic devices such as handheld electronic devices (e.g., mobile phones, media players, personal digital assistants, remote controls, etc.). The apparatus, systems and methods can also be used for glass covers or displays for other relatively larger form factor electronic devices (e.g., portable computers, tablet computers, displays, monitors, televisions, etc.). In these embodiments, the glass substrate with diamond coating can form part of a display area of an electronic device (e.g., situated in front of a display either as a separate part or integrated within the display). Alternatively or additionally, the glass member may form a part of the housing. For example, it may form an outer surface other than in the display area.

Glass or other transparent substrate thickness can be less than 5 mm and, in some embodiments, have a thickness between 0.5 and 3 mm. In particularly thin embodiments, the thickness of the glass substrate can be between 0.3 and 1 mm. In some embodiments, thickness of a glass substrate can be between 0.25-3 mm. In other embodiments, thickness can be less than 2 mm, less than 1 mm, or less than 0.6 mm.

In one embodiment, forming glass substrate edges to correspond to a particular predetermined geometry and providing chemical modification can cause compression in the vicinity of the edges of the glass cover to be enhanced. The glass cover can thereby be made stronger by imposing the particular predetermined geometry on the edges of the glass cover. In one embodiment, surfaces, e.g., edges, of the glass cover can be chemically modified. In one embodiment, the edge geometry is configured to reduce or smooth out sharp transitions, such as corners.

In some embodiments one or more edges of the glass substrate can be curved or chamfered. A chamfer is a beveled edge that substantially connects two sides or surfaces (e.g., top and bottom surfaces). By way of example, edge geometry may include a chamfered edge of between 0.2 millimeter and 0.5 millimeters, extending at least partially between top and bottom sides of the glass substrate. Advantageously, use of the chamfered edge can reduce compressive stresses. Alternatively or in addition, in one embodiment, a glass substrate edge can include a smoothed corner, where for example a corner between a first surface and a second surface (e.g., top/bottom surface and a side surface that is substantially perpendicular) can be rendered less sharp. As another example, transition between a top surface to a side surface or between a bottom surface and a side surface can be smoothed. In some embodiments, edges of glass can be rounded by a predetermined edge geometry having a predetermined edge radius (or predetermined curvature) of at least 10% of the thickness applied to the corners of the edges of the glass. In other embodiments, the predetermined edge radius can be between 20% to 50% of the thickness of the glass. In one embodiment, a glass cover can extend to the edge of a housing of an electronic device without a protective bezel or other barrier. In one embodiment, the glass cover can include a bezel that surrounds the respective edges. The glass cover can be provided over or integrated with a display, such as a Liquid Crystal Display (LCD) display usable in a smartphone, watch, or tablet.

In some embodiments, a glass substrate structure can be subject to optional processing steps. Such processing steps can include applying one or more additional coatings or laminates (e.g., organic, polymer, inorganic, or graphene) to the glass substrate. In some embodiments, the entire substrate can have additional coatings, while in other embodiments at least one of a top, bottom, edge, or corner of the glass substrate can be provided with coatings.

In some embodiments, before deposition of a diamond or diamond like coating or film, a substrate can be treated by sputtering, evaporation, atomic layer deposition (ALD), chemical vapor deposition, plasma, thermal form of deposition of one or more of materials including but not limited to oxides and nitride dielectric materials, oxides of metals such as titanium, indium, tin, zinc, or combinations, oxides of graphene such as graphene oxide, reduced fluorinated graphene oxide, oxides of silicon, titanium, or aluminum, oxynitrides, nitrides of aluminum, silicon, titanium, boron, and metals such as tungsten or titanium. These intermediate materials can enable or enhance 1) adhesion of subsequent layers, 2) system optical properties such as transmission and reflection, 3) system stress through of thermal coefficient of enhancement transitioning, 4) reduced surface roughness, and other properties. In some embodiments, for metal deposited via sputter deposition, power levels can be adjusted, and shutter opening times can vary to achieve the target thickness uniformly across the display glass surface. For oxides and nitrides, thin films may utilize lower temperature (including temperatures less than or equal to 600° C.). Advantageously in some embodiments this can reduce coefficient of thermal expansion differences, reducing interlayer and subsurface stress, and allow for tuning coloration and visual uniformity, as well as optical losses attributable to haze or reflectance.

To encourage growth of diamond layers or films with selected grain sizes or in defined areas, a substrate can be seeded with diamond crystal particulates. Seed layers can be formed through the use of selective deposition or etched seed areas. In some embodiments, nanocrystalline diamonds can be directly deposited or deposited in a solution. In some embodiments, seed size can range from 5 to 50 nanometers. Seeds can be functionalized, or can have a positive, negative, or neutral zeta potential. The seed crystals may be in a solvent, dimethyl sulfoxide, oil, photoresist, deionized water, a combination or similar types of suspension or matrix. Substrate coverage with diamond crystal seeds can be uniformly distributed at 105-1013 grains per square centimeter, non-uniform, or localized in selected areas using masks, selective spraying, electrospraying, ultrasonic spraying, sonication, or other form of spatially localized application. In some embodiments seeds of differing sizes and characteristics can be used.

In some embodiments, a diamond layer formed on a diamond seeded substrate can have a sp2 concentration of less than 20% by diamond layer volume. In other embodiments, a diamond layer can have a grain orientation at least 80% in either the <111> or <100> crystalline direction. In still other embodiments, a highly oriented diamond film can include differing crystal orientations in selected region or layers, with <111> and <100> crystalline direction respectively predominating.

Properties of diamond can be measured and characterized using Raman spectroscopy. Cubic diamond has a single Raman-active first order phonon mode at the center of the Brillouin zone. The presence of sharp Raman lines allows cubic diamond to be recognized against a background of graphitic or other carbon crystal types. Small shifts in the band wavenumber can indicate diamond composition and properties. In some embodiments, the full width half maximum (FWHM) obtained from Raman characterization at a wave number of 1332 cm−1 for the diamond layers or films formed as indicated in this disclosure can be between 5 and 20 cm−1 for SiN or other suitable buffer layer coated glass and between 20 and 85 cm−1 for RIE (reactive ion etched) or other surface treated glass. In other embodiments, a deposited diamond layer can be measured to have a relative magnitude at 1332 cm−1 and greater than or equal to 0.5:1 as compared to magnitude at 1400-1600 cm−1 by Raman analysis. In other embodiments, a diamond layer can have physical properties such as Vickers hardness measured by nanoindentation of at least 12 Gigapascal. In other embodiments Vickers hardness can be greater than 20 Gigapascal. In other embodiments, a diamond layer can be measured to exert a compressive stress less than 50 Gigapascal.

In some embodiments, polycrystalline diamond or diamond-like carbon (DLC) coatings or materials can be formed on all or at least a portion of a substrate. In some embodiments, polycrystalline diamond grains sized to be less than 1 micron (1000 nanometers) and greater than 500 nanometers can be used. In other embodiments, polycrystalline diamond or diamond-like material can include ultrananocrystalline (UNCD) grain sizes (2-10 nanometers), nanocrystalline grain sizes (10-500 nanometers), or microcrystalline grain sizes (500 nanometers or greater). In some embodiments, diamond grain size can include a range of grain sizes, including larger and smaller grains. In some embodiments, a diamond layer can be formed to have grains of less than 1 micron. In some embodiments, grain size can differ by greater or less than 50%, 100%, 200% or 500% of mean diamond grain size. In other embodiments, diamond grain size can be maintained to within 50%, 20%, or 10% of mean grain size. In some embodiments, 50%, 60%, 80%, or 90% of the diamond grains can be sized between 50 and 500 nanometers. In some embodiments, a diamond layer can be formed from at least 90% nanocrystalline diamond and have diamond grains sized between 2 nanometers and 500 nanometers. In some embodiments, a diamond layer can be formed from at least 90% microcrystalline diamond and have diamond grains sized between 500 nanometers and 1000 nanometers. In other embodiments, diamond grains can be sized between 500 nanometers and 1000 nanometers. In other embodiments, 90% of the diamond grains can be sized between 200 and 300 nanometers.

Diamond layer thickness in some embodiments can be selected to be between 20 nanometers and 1000 nanometers. Typically diamond grain size will be less than diamond layer thickness and can be less than 50% of diamond layer thickness in some embodiments. In some embodiments useful for optical coatings, diamond layer thickness will be between 20 and 500 nanometers. For example, in one embodiment a glass or other transparent material can be coated with a diamond film having a thickness between 70 and 300 nanometer thickness.

Diamond layers can have a substantially uniform thickness over all or defined portions of a surface or substrate. In other embodiments, thickness can be non-uniform, and vary over portions of a surface or substrate. In some embodiments diamond layers can be conformal when extending over cavities, depressions, or protrusions in a substrate or surface. In some embodiments, diamond layers can steadily thin or thicken away from one or more positions on a substrate.

Multiple diamond layers distinguished by composition, crystal structure, dopants, grain size, or grain size distribution can be a part of a multilayer coating or film system applied to a substrate. Distinct diamond layers can be layered on top of diamond layers or non-diamond materials. In certain embodiments, physical parameters of diamond layers can continuously or semi-continuously change vertically or laterally through the layer.

In particular embodiments, the diamond layer has a thickness, for example, between 30 nanometers and 150 nanometers (e.g., 30 nanometers, 40 nanometers, 50 nanometers, 60 nanometers, 70 nanometers, 80 nanometers, 90 nanometers, 100 nanometers, 110 nanometers, 120 nanometers, 130 nanometers, 140 nanometers, or 150 nanometers inclusive of all ranges and values there between). Furthermore, the diamond layer can have a root mean square (RMS) surface roughness of less than 2 nanometers. In particular embodiments, the diamond layer can have a root mean square (RMS) surface roughness of less than 11, 10, 9, 8, or 7, 6, 5, 4, 3, or 2 nanometers. In some embodiments, the diamond layer can have an RMS roughness of less than 50%, 40%, 30%, 20%, or 10% of the film thickness. In some embodiments, the diamond layer can have an RMS roughness of less than 20% of the diamond layer thickness.

Diamond or DLC can be deposited by chemical vapor deposition (CVD) such as hot filament CVD, microwave CVD, rf-CVD, laser CVD (LCVD), or laser ablation, metal-organic CVD (MOCVD), sputtering, thermal evaporation PVD, ionized metal PVD (IMPVD), electron beam PVD (EBPVD), reactive PVD, cathodic arc, and the like. CVD involves the use of a diluted mixture of a carbon containing gas such as carbon dioxide or hydrocarbons, typically methane, and hydrogen whereby the carbon containing component content usually varies from about 0.1% to 4% of the total volumetric flow. In one of these techniques, the gas mixture is energized using a metallic filament, usually tungsten which is electrically heated to a temperature ranging from about 170° C. to 2400° C. The gas mixture disassociates at the filament surface and carbon, hybridized in the form of diamond, is deposited onto a substrate placed below the filament. In operation, power density at the substrate can be between 300-600 W/m2/min. Deposition usually occurs at sub-atmospheric pressures in the range of 30 mTorr to 300 Torr.

In some embodiments, a thin diamond film can be deposited on a substrate having a substrate temperature of less than 600 degrees Celsius. In other embodiments, deposition can be at temperatures between 300 and 600 degrees Celsius. Advantageously, as compared to typical 700-800 degree Celsius temperatures for conventional CVD mediated diamond film growth, such low temperatures greatly reduce thermal effects, including thermal degradation, stress due to differing CTE, or warping of the substrate. Advantageously, this can allow for a greater variety of substrates or coatings to be used.

In some embodiments, various processes can be used to improve diamond or other film quality. These processes can be done, for example, before seeding, before layer deposition, after layer deposition, or after metrology steps that contaminate the surface. For example, a substrate can be subjected to dry and/or wet processing, including but not limited to strong or weak acid and/or base cleaning, solvent cleaning, ultrasonic agitation, plasma cleaning, ultraviolet (UV), ozone treatment, application of tetramethyl ammonium hydroxide, or any other suitable combination of processes. Plasma cleaning can include subjecting a substrate to plasma derived from argon and/or oxygen in various concentrations. Post diamond deposition cleaning processes can be included such as: solvent clean that includes solvents such as: acetone and IPA, and plasma clean with O2/Ar gases using RIE or similar to clean the substrates to remove any unwanted residue deposited during the diamond deposition processes.

In some embodiments a glass or other substrate can support multiple thin diamond layers, various interlayers, layers pre-treated using reactive ion etching (RIE) or other techniques, and a top layer. These can be thin single or multiple layers of metals, ceramics, glasses, or other compositions. Thickness of such layers can be less than 1000 nanometers. Such layers can act as cap layers, intermediate layers, or buffer layers, and can improve optical, electrical, thermal, or mechanical properties of the multilayer structure. In some embodiments, cap, intermediate, or buffer layers can be transparent and include one or more of metals (e.g., tungsten or titanium); ceramics, dielectric materials, or glass (e.g., aluminosilicate or borosilicate). In some embodiments, cap layers, intermediate layers, or buffer layers can include one or more of indium tin oxide, aluminum oxide, oxynitrides, titanium oxides including but not limited to titanium dioxide, magnesium oxide, silicon dioxide, and hafnium oxide. In other embodiments, cap layers, intermediate layers, or buffer layers can include one or more of nitrides of aluminum, silicon, titanium, or boron. Cap layers, intermediate layers, or buffer layers can also include but are not limited to carbon film formed of diamond-like carbon (DLC), amorphous carbon or nano-crystal diamond (NCD), or a metal film made of molybdenum, titanium, tungsten, chromium or copper, or a ceramic film formed of SiC, TiC, CrC, WC, BN, B4C, Si3N4, TIN, CrN, SiCN, or BCN. The thickness of cap layers, intermediate layers, or buffer layers can range from 2 nanometers to 1000 nanometers.

In some embodiments, a deposited diamond film can be cleaned, and exposed to a two-dimensional top layer material, such as reduced fluorinated graphene oxide, graphene, graphene oxide, or f-silane. In some embodiments this provides for superhydrophobicity or oleophobicity without significant degradation to diamond film properties, including optical transmissivity and/or hardness. In one embodiment, graphene oxide may come from a chemical suspension of multilayer graphene oxide and spun on to the diamond film, and either wet chemically or dry chemically (plasma) reduced through inclusion of fluorine atoms into the material, in substitution to oxygen.

In some embodiments, a substrate and/or diamond layer may be subjected to surface functionalization treatment steps. This can include surface functionalization by wet chemistry using spray coating, biased spray coating, ultrasonic spray coating, ultrasonic agitation of solvent and ketone mixtures, including but not limited to methanol, acetone, isopropyl alcohol, ethanol, butanol, or pentanol. The functionalized surface can include hydrocarbon chains, hydroxyl bonds, oxygen termination, or other suitable chemically active materials.

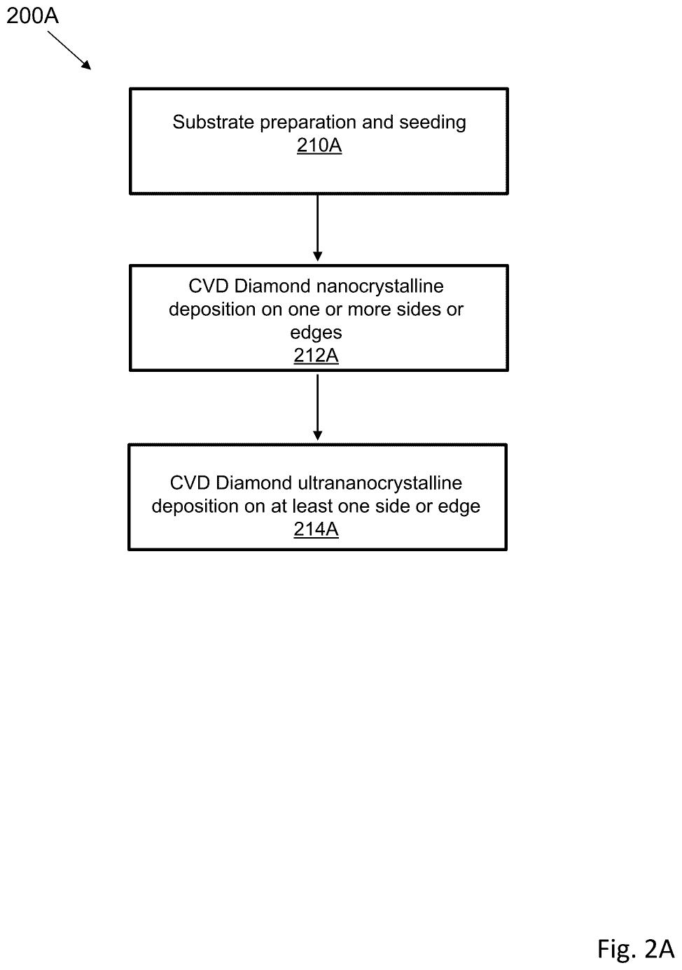

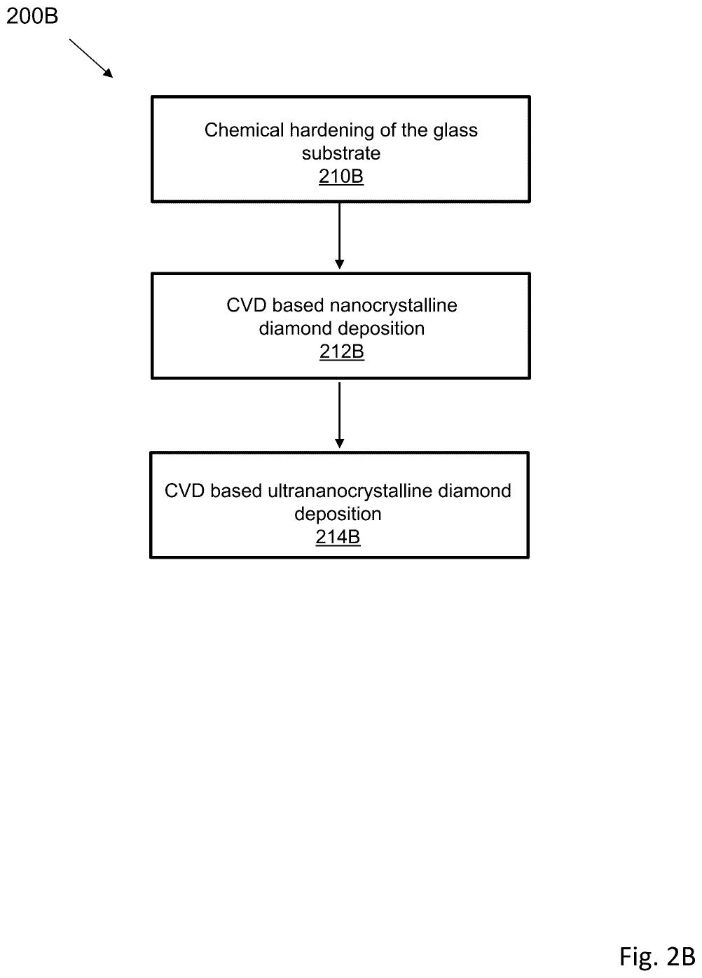

FIG. 2A is an exemplary block diagram of an embodiment of a method for fabricating a chemically modified glass substrate structure with nanocrystalline (NCD) and ultrananocrystalline (UNCD) diamond layers such as illustrated with respect to FIG. 1A. In this embodiment, in a first step 210A a glass substrate is cleaned and prepared by seeding with nanocrystalline diamonds. In a second step 212A CVD diamond is formed on at least a first side. The first side can be one of a top, bottom, edge, or corner. In addition to a first side, in some embodiments additional second, third, etc., sides can be coated with CVD diamond. In step 214B CVD ultrananocrystalline diamond is formed on at least the first side and optionally on other sides or edges.

FIG. 2B is an exemplary block diagram of an embodiment of a method for fabricating a chemically modified glass substrate structure with nanocrystalline (NCD) and ultrananocrystalline (UNCD) diamond layers such as illustrated with respect to FIG. 1B. In this embodiment, in a first step 210B, ion substitution is used to chemically modify at least a first and second side of the glass substrate structure. The second side can be one of a top, bottom, edge, or corner. In step 212B CVD nanocrystalline diamond is formed on at least a first side. The first side can be one of a top, bottom, edge, or corner. In addition to a first side, in some embodiments additional second, third, etc., sides can be coated with CVD diamond. In step 214B, CVD ultrananocrystalline diamond is formed on at least the first side. The first side can be one of a top, bottom, edge, or corner. In addition to a first side, in some embodiments additional second, third, etc., sides can be coated with CVD ultrananocrystalline diamond. In some embodiments, optional processing steps can include applying laminates (e.g. organic, polymer, inorganic, or graphene coatings) to at least one of a top, bottom, edge, or corner chemically modified glass substrate structure.

In some embodiments the substrate can be exposed to gas. In other embodiments, use of a cooled substrate wafer stage can maintain temperatures at or below 500 degrees Celsius allowing multilayer integration without exceeding stress, softening, and strain limitations of the underlying material layers. Typically diamond growth process energy is substantially derived from thermally activated filament sources or microwave activated plasma sources. Deposition or provision of further surface treatment, surface polishing, and packaging of the diamond layer and diamond structure.

In some embodiments, single or multiple diamond layers or films can include multilayer structures that enable or enhance various usages or features, including those that provide for anti-reflective (AR) layers, light redirection, light interference, cover glass functionality, protective covers, hydrophobic or oleophobic coatings, use in displays or windows, or chemical, thermal, or mechanical protection. Applications or components supporting multilayer diamond layers, films, or coatings can include but are not limited to visible or infrared optics, windows, optical waveguides, semiconductors, semiconductor coatings, and rugged or durable coatings for electronics, manufacturing, or tooling. Other applications for diamond multilayer coatings can include use in biological substrates or medical devices, or use in batteries, fuel cells, electrochemical systems, chemo-sensors, general sensing, or integration with other advanced materials.

When used in optically transmissive systems, the diamond film provides transmission of light through the glass substrate and the diamond film at 550 nanometer wavelength is in excess of 0.60, 0.70, 0.80 or 0.90, the transmission of light between 350 nanometer and 450 nanometer wavelength is less than 0.60, 0.70, 0.80 or 0.90, and the transmission of light between 750 nanometer and 850 nanometer of less than 0.60, 0.70, 0.80 or 0.90. In other embodiments of optically transmissive systems, the diamond film provides transmission of light through the glass substrate and the diamond film with a transmissivity in excess of 0.60, 0.70, 0.80 or 0.90 at wavelengths ranging between 500 and 600 nanometers, 530 and 570 nanometers, or 540 and 560 nanometers. In some embodiments a glass or other transparent material can be coated with a diamond film that provides haze of less 20% for thick diamond layers (e.g. ranging from 1 micron to 10 microns), less 10% for thin diamond layers (e.g. ranging from 200 nanometers to 1000 nanometers), and less 5% for very thin diamond layers (e.g. below 200 nanometers). In other embodiments, thicker diamond layer coatings of up to 10 microns can be used to improve mechanical, frictional, or thermal characteristics.

Diamond layers can have a substantially uniform thickness over all or defined portions of a surface or substrate. In other embodiments, thickness can vary over portions of a surface or substrate. In some embodiments diamond layers can be conformal when extending over cavities, depressions, or protrusions in a substrate or surface. In some embodiments, diamond layers can steadily thin or thicken away from one or more positions on a substrate. In some embodiments, thinning or thickening can be less than 20%, 10%, 6%, or 3% of diamond layer thickness over the substrate.

As will be understood, the described diamond layers, substrates, and thin films of non-diamond materials can include various embodiments, characteristics, and combinations, including but not limited to the following additional examples:

Example 1—In a first example, a multilayer transparent diamond structure including nanocrystalline and ultrananocrystalline diamond layers can be continuously and conformally coated over a transparent glass substrate to act as an optically clear protective coating suitable for smart phones, tablets, or laptops. For example, a substantially uniform 70-110 nanometers thick nanocrystalline diamond film having a grain size ranging between 20 to 70 nanometers can be deposited on a conductive indium tin oxide (ITO) film that is deposited on the transparent glass substrate. In some embodiments, an ultrananocrystalline diamond layers having a thickness of between 20 and 500 nanometers with grain sizes between 2 and 10 nanometers can be deposited on the nanocrystalline diamond layer. In some embodiments, an ultrananocrystalline diamond layer can have a thickness of between 20 and 200 nanometers with diamond grain sizes between 2 and 10 nanometers. In some embodiments, an ultrananocrystalline diamond layer can have a thickness of less than 50 nanometers, with at least 50% of ultrananocrystalline diamond grains sized between 2 nanometers and 10 nanometers. Optionally a hydrophobic coating or additional diamond coating doped or functionalized to support a hydrophobic or oleophobic coating can be deposited on the ultrananocrystalline diamond layer. The glass substrate can be chemically cleaned using acetone, followed by cleaning using UV ozone. Alternatively, float glass or similar substrates can be acid cleaned to remove tin or other metallic coatings. In some embodiments the glass surface can be functionalized to include hydrocarbon chains derived from solvent breakdown while drying.

A conventional HF CVD reactor with tungsten, tantalum, or rhenium filaments can be used. Filament diameter, spacing, and number can be adjusted to provide best results. In one embodiment, filament diameter 0.12 to 0.5 mm, spacing can be 8 to 30 mm, and between 7 to 28 filaments used. Chambers can be of any suitable shape, including spherical, rectangular, or cylindrical. In one embodiment, a cylindrical sphere can be sized to have a volume between 100 to 200 liters, with diameter between 30 to 150 centimeters.

The reactor can include a stage capable of supporting heating or cooling of the substrate. In some embodiments the reactor stage can be set to provide a substrate deposition temperature between 500 and 600 C. At these temperature ranges, diamond layer deposition rates can be between 10 to 100 nanometers per hour, or in other embodiments can be less than 10 nm per hour.

Precursor gases including methane, hydrogen, oxygen, and argon can be introduced into the chamber at a pressure of 5-50 Torr. In particular, addition of less than 1% oxygen can lower required temperature to maintain an expected deposition rate, and oxygen will preferentially etch sp2 deposited areas. Methane concentration can be between 0.5 to 5 percent of total gas volume. Hydrogen concentration can be between 60 to 98 percent of total gas volume. Argon concentration can be between 0 to 40 percent of total gas volume.

To ensure consistent grain size, the substrate can be coated with diamond seeds dispersed in a dimethyl sulfoxide (DMSO) or other solvent solutions including but limited to ethanol, methanol, IPA, acetone and DI water. In some embodiments, 5 to 50 nanometer grain sizes can be used.

In some embodiments, the diamond film is continuous and conformal over the substrate.

Further, the diamond film can have a FWHM of 5-7 and an sp2 concentration of less than 20% by volume, a grain orientation of at least 80% in the <111> crystalline direction, a Raman spectrographic signature of diamond (approximately 1332 nm) of between 0.7:1 and 1.2:1 as compared to peak Graphitic Band (1400-1600 nm) by Raman Analysis, a Vickers hardness of between 20 and 60 Gigapascal, and with transmission of light through the glass substrate and the diamond film at 550 nanometer wavelength is in excess of 0.70, a haze of less than 5%.

Example 2—In a second example, a substrate can be coated with a substantially uniform 100-2000 nanometers thick nanocrystalline diamond layer or film having a grain size ranging between 100 to 2000 nanometers, as well as a thinner ultrananocrystalline diamond layer. In some embodiments, ultrananocrystalline diamond layers can have a thickness of between 20 and 200 nanometers with grain sizes between 2 and 10 nanometers. In some embodiments, ultrananocrystalline diamond layers can have a thickness of less than 50 nanometers, with at least 50% of ultrananocrystalline diamond grains sized between 2 nanometers and 10 nanometers. In one embodiment, the 100-2000 nanometers thick nanocrystalline diamond film and covering ultrananocrystalline diamond layer and can be further etched, with additional layers or films being selectively applied to fill in etched diamond and support formation of waveguides for data transfer. In some embodiments, the deposited grain size can include diamond grains ranging from 5 nanometers to 50 nanometers.

The reactor can include a stage capable of supporting heating or cooling of the substrate. In some embodiments the reactor stage can be set to provide a substrate deposition temperature between 500 and 800 C. At these temperature ranges, diamond layer deposition rates can be between 10 to 200 nanometers per hour.

The substrate can be coated with diamond seeds dispersed in a DMSO or other solvent solutions including but limited to ethanol, methanol, IPA, acetone, and DI water. In some embodiments, 5 to 150 nanometer grain sizes can be used, with larger grains typically being reduceable in size by sonication or other processing steps. Various grain sizes or grain size ranges can be used in some embodiments, including co-deposited small and large grain sizes. In some embodiments, the seeds are deposited in a manner that ensures that the film is continuous and conformal over the substrate.

In some embodiments, the diamond layer or film can have a Young's modulus in excess of 80 Gigapascal.

Example 3—In a third example, a substrate can be coated with multiple layers, including diamond layers, ceramic layers, or metal layers. In some embodiments, a substantially uniform 5-50 nanometers thick nanocrystalline diamond layer or film having a grain size ranging between 5 to 50 nanometers can be deposited. In some embodiments, an ultrananocrystalline diamond layer can be deposited that can have a thickness of between 20 and 200 nanometers with grain sizes between 2 and 10 nanometers. In some embodiments, ultrananocrystalline diamond layers can have a thickness of less than 50 nanometers, with at least 50% of ultrananocrystalline diamond grains sized between 2 nanometers and 10 nanometers.

The reactor can include a stage capable of supporting heating or cooling of the substrate. In some embodiments the reactor stage can be set to provide a substrate deposition temperature between 500 and 600 C. At these temperature ranges, diamond layer deposition rates can be between 10 to 100 nanometers per hour.

In the foregoing description, reference is made to the accompanying drawings that form a part thereof, and in which is shown by way of illustration specific exemplary embodiments in which the disclosure may be practiced. These embodiments are described in sufficient detail to enable those skilled in the art to practice the concepts disclosed herein, and it is to be understood that modifications to the various disclosed embodiments may be made, and other embodiments may be utilized, without departing from the scope of the present disclosure. The foregoing detailed description is, therefore, not to be taken in a limiting sense.

Reference throughout this specification to “one embodiment,” “an embodiment,” “one example,” or “an example” means that a particular feature, structure, or characteristic described in connection with the embodiment or example is included in at least one embodiment of the present disclosure. Thus, appearances of the phrases “in one embodiment,” “in an embodiment,” “one example,” or “an example” in various places throughout this specification are not necessarily all referring to the same embodiment or example. Furthermore, the particular features, structures, databases, or characteristics may be combined in any suitable combinations and/or sub-combinations in one or more embodiments or examples. In addition, it should be appreciated that the figures provided herewith are for explanation purposes to persons ordinarily skilled in the art and that the drawings are not necessarily drawn to scale.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims. It is also understood that other embodiments of this invention may be practiced in the absence of an element/step not specifically disclosed herein.

We claim:

1. A diamond coated glass structure, comprising:
a transparent substrate;
a deposited nanocrystalline diamond coated on the transparent substrate; and
an ultrananocrystalline diamond layer deposited on the nanocrystalline diamond; and
wherein the combination of deposited nanocrystalline diamond and ultrananocrystalline diamond have less than 9 nanometer RMS surface roughness.

2. The structure of claim 1, wherein the deposited nanocrystalline diamond and ultrananocrystalline diamond layer together have thickness between 20 and 500 nanometers.

3. The structure of claim 1, wherein the deposited nanocrystalline diamond and ultrananocrystalline diamond layer together comprise a 70-500 nanometers thick film having at least 50% of diamond grains sized between 3 nanometers and 150 nanometers.

4. The structure of claim 1, wherein the ultrananocrystalline diamond layer comprises a diamond layer having thickness of less than 500 nanometers.

5. The structure of claim 1, wherein the ultrananocrystalline diamond layer comprises a less than 500 nanometers thick diamond film having at least 50% of diamond grains sized between 2 nanometers and 10 nanometers.

6. The structure of claim 1, wherein the transparent substrate is sized to be to have an area of at least one square centimeter.

7. The structure of claim 1, wherein the transparent substrate is a glass that comprises at least one of a soda, aluminosilicate glass, borosilicate glass, alkali silicate glass, soda lime glass, an alkali aluminosilicate glass, an alkali aluminogermanate glass, an alkali germanate glass, and an alkali gallogermanate glass.

8. The structure of claim 1, wherein the transparent substrate is chemically modified with ion substitution.

9. The structure of claim 1, wherein the transparent substrate is chemically modified by replacement of at least some sodium ions with potassium ions.

10. The structure of claim 1, wherein the transparent substrate is chemically modified by ion substitution replacement of at least some ions to a penetration depth of less than 100 microns.

11. The structure of claim 1, wherein at least one additional coating is deposited on the ultrananocrystalline diamond layer.

12. The structure of claim 1, wherein the ultrananocrystalline diamond layer and the nanocrystalline diamond layer cover a top surface and at least one of a side surface of the transparent substrate.

13. The structure of claim 1, wherein the ultrananocrystalline diamond layer has a thickness less then thickness of the nanocrystalline diamond layer.

14. The structure of claim 1, wherein the ultrananocrystalline diamond layer comprises a less than 500 nanometers thick diamond film having at least 50% of diamond grains sized between 2 nanometers and 10 nanometers.

15. A method of forming a diamond coated glass structure, comprising:
providing a transparent substrate;
depositing nanocrystalline diamond coated on the transparent substrate; and
depositing an ultrananocrystalline diamond layer on the deposited nanocrystalline diamond; and
wherein the combination of deposited nanocrystalline diamond and ultrananocrystalline diamond have less than 9 nanometer RMS surface roughness.

16. The method of claim 15, wherein the nanocrystalline diamond layer comprises a diamond layer having thickness of less than 500 nanometers.

17. The method of claim 15, wherein the deposited nanocrystalline diamond and ultrananocrystalline diamond layer together comprise a 70-500 nanometers thick film having at least 50% of diamond grains sized between 3 nanometers and 150 nanometers.

18. The method of claim 15, wherein the ultrananocrystalline diamond layer comprises a diamond layer having a thickness less than 500 nanometers.

19. The method of claim 15, wherein the transparent substrate is a glass that comprises at least one of a soda, aluminosilicate glass, borosilicate glass, alkali silicate glass, soda lime glass, an alkali aluminosilicate glass, an alkali aluminogermanate glass, an alkali germanate glass, and an alkali gallogermanate glass.
